(19) United States
(12) Patent Application Publication
(10) Pub. No.: US 2012/0006582 A1
(43) Pub. Date: Jan. 12, 2012

(54) FLEXIBLE BOARD FOR TRANSMITTING SIGNALS

(76) Inventors: Yong Goo LEE, Seoul (KR); Kyoung il KANG, Gyeonggi-do (KR); Kyung Hun JUNG, Gyeonggi-do (KR)

(21) Appl. No.: 13/177,213

(22) Filed: Jul. 6, 2011

(30) Foreign Application Priority Data
Jul. 6, 2010 (KR) 10-2010-0064944

(51) Int. Cl. H05K 1/02

(52) U.S. Cl. 174/254

(57) ABSTRACT

Provided is a flexible board for transmitting signals which includes: a dielectric on which different signal lines are respectively disposed on independent separation regions on opposite surfaces of opposite sides thereof; a metallic shielding portion that is spaced apart from each other at intervals at a boundary between the separation regions and shields interference between the different signal lines; and a ground conductive layer that is formed on a portion of the dielectric and is electrically connected to the metallic shielding portion.

### CROSS-REFERENCE TO RELATED PATENT APPLICATION

This application claims the benefit of Korean Patent Application No. 10-2010-0064944, filed on Jul. 6, 2010, in the Korean Intellectual Property Office, the disclosure of which is incorporated herein in its entirety by reference.

### FIELD

The present disclosure relates to a flexible board for transmitting signals. More particularly, the present disclosure relates to a flexible board for transmitting signals in which a high frequency signal transmission line and a data signal line are disposed on opposite surfaces of opposite sides of an identical board, and interference between signal lines is shielded.

### BACKGROUND

Typically, mobile communication devices, such as a mobile phone, use a flexible circuit board for electrical signal connection between a circuit board and a liquid crystal display (LCD) window.

In such mobile communication devices, data are transmitted from a main memory installed on the circuit board and displayed on the LCD window. Also, mobile communication devices include an antenna for wireless communication with others and for receiving information without wire from the outside. Conventionally, an antenna is electrically connected using a high frequency transmission line using a high frequency circuit portion, a coaxial cable, or a flexible circuit board.

Also, mobile communication devices may further include a data transmission line for transmitting data from the circuit board to the LCD.

Accordingly, mobile communication devices include lines for transmitting different signals.

Since the high frequency transmission line and the data transmission line are used to transmit different signals, interference between signals may occur.

To prevent the occurrence of the signal interference, conventionally, the high frequency transmission line and the data transmission line are individually disposed in independent dielectrics, and also, arranged spaced apart from each other, in mobile communication devices.

However, like in conventional cases, if lines are individually manufactured and installed inside mobile communication devices, spatial utilization in the limited space of mobile communication devices, which tend to be manufactured in small sizes, are lowered.

Also, conventionally, separate line manufacturing leads to high manufacturing costs.

### SUMMARY

This section provides background information related to the present disclosure which is not necessarily prior art.

The present disclosure provides a flexible board for transmitting signals in which a high frequency signal transmission line and a data signal line are disposed on opposite surfaces of opposite sides of an identical board, and interference between different signal lines is shielded to reduce a noise of a high frequency signal, thereby increasing spatial utilization of a limited inner space of a mobile communication device and reducing line manufacturing costs.

According to an aspect of the present disclosure, there is provided a flexible board for transmitting signals.

Board Including Metallic Shielding Portion Formed as Viaholes.

The flexible board for transmitting signals includes: a dielectric on which different signal lines are respectively disposed on independent separation regions on opposite surfaces of opposite sides thereof; a metallic shielding portion that is spaced apart from each other at intervals at a boundary between the separation regions and shields interference between the different signal lines; and a ground conductive layer that is formed on a portion of the dielectric and is electrically connected to the metallic shielding portion.

In this regard, the different signal lines include a high frequency signal transmission line for transmitting a high frequency signal, and a data signal line for transmitting a data signal, the separation regions include a first separation region on which the high frequency signal transmission line is formed, and a second separation region on which the data signal line is formed, and the boundary is formed between the first separation region and the second separation region.

Also, the ground conductive layer may be formed including the boundary on an outer surface of the dielectric facing the first separation region.

Also, the ground conductive layer may include: a first ground conductive layer formed including the boundary on an outer surface of the dielectric facing the first separation region; and a second ground conductive layer formed including the boundary on an outer surface of the dielectric facing the second separation region.

The metallic shielding portion may include: a plurality of viaholes that are spaced apart from each other at intervals and pass through the dielectric; and a metallic material that fills the viaholes.

According to another aspect of the present disclosure, there is provided a flexible board for transmitting signals.

Board Including Metallic Shielding Portion Having Planar Shape.

The flexible board for transmitting signals includes: a dielectric on which different signal lines are respectively disposed on independent separation regions on opposite surfaces of opposite sides thereof; a metallic shielding portion that is disposed as one body at a boundary between the separation regions and shields interference between the different signal lines; and a ground conductive layer that is formed on a portion of the dielectric and is electrically connected to the metallic shielding portion.

In this regard, the different signal lines include a high frequency signal transmission line for transmitting a high frequency signal, and a data signal line for transmitting a data signal, the separation regions include a first separation region on which the high frequency signal transmission line is formed, and a second separation region on which the data signal line is formed, and the boundary is formed between the first separation region and the second separation region.

Also, the ground conductive layer is formed including the boundary on an outer surface of the dielectric facing the first separation region.

The ground conductive layer includes: a first ground conductive layer formed including the boundary on an outer surface of the dielectric facing the first separation region; and a second ground conductive layer formed including the boundary on an outer surface of the dielectric facing the second separation region.

The metallic shielding portion may be formed in a planar shape, and may include a separation hole that is formed in a planar shape having a predetermined width along the boundary and passes through the dielectric, and a metallic material that fills the separation hole.

According to another aspect of the present disclosure, there is provided a flexible board for transmitting signals.

Board Including Shielding Film.

The flexible board for transmitting signals includes: a dielectric on which different signal lines are respectively disposed on independent separation regions on opposite surfaces of opposite sides thereof; a spatial portion that vertically passes through the dielectric at a boundary between the separation regions; a pair of ground conductive layers respectively formed on surfaces of the dielectric facing the separation regions; and a shielding film that is disposed contacting each of upper and lower surfaces of the dielectric above and under the dielectric to surround the spatial portion and any one of the separation regions, and that shields interference of the different signal lines.

The different signal lines include a high frequency signal transmission line for transmitting a high frequency signal, and a data signal line for transmitting a data signal, the separation regions include a first separation region on which the high frequency signal transmission line is formed, and a second separation region on which the data signal line is formed, the boundary is formed between the first separation region and the second separation region, and the shielding film surrounds the second separation region.

The flexible board may further include a data signal line disposed on the surface of the dielectric facing the first separation region.

The shielding film may include a pair of shield films, which are respectively disposed above and under the dielectric, wherein each shielding film includes an adhesive layer attached on a surface of the dielectric, and a protection film layer formed on an outer surface of the adhesive layer.

In this regard, a silver (Ag) powder layer including silver powder may be further formed between the adhesive layer and the protection film layer.

### BRIEF DESCRIPTION OF THE DRAWINGS

The drawings described herein are for illustrative purposes only of selected embodiments and not all possible implementations, and are not intended to limit the scope of the present disclosure. The attached drawings may be useful to understand the features and advantages of the present disclosure:

FIG. 1 is a perspective view of a flexible board for transmitting signals according to an embodiment of the present disclosure;

FIG. 2 is a cross-sectional view taken along a line I-I′ of FIG. 1;

FIG. 3 is a perspective view of the flexible board for transmitting signals of FIG. 1 that further includes a ground conductive layer;

FIG. 4 is a cross-sectional view taken along a line II-II′ of FIG. 3;

FIG. 5 is a perspective view of a flexible board for transmitting signals according to a second embodiment of the present disclosure;

FIG. 6 is a plan view of a flexible board for transmitting signals according to a third embodiment of the present disclosure;

FIG. 7 is a cross-sectional view taken along a line III-III′ of FIG. 6, before a shielding film is attached; and

FIG. 8 is a cross-sectional view taken along a line III-III′ of FIG. 6, after a shielding film is attached.

### DETAILED DESCRIPTION

Hereinafter, a flexible board for transmitting signals according to embodiments of the present disclosure is further described with reference to the attached drawings.

### Example 1

### Board Including Metallic Shielding Portion Formed as Viaholes

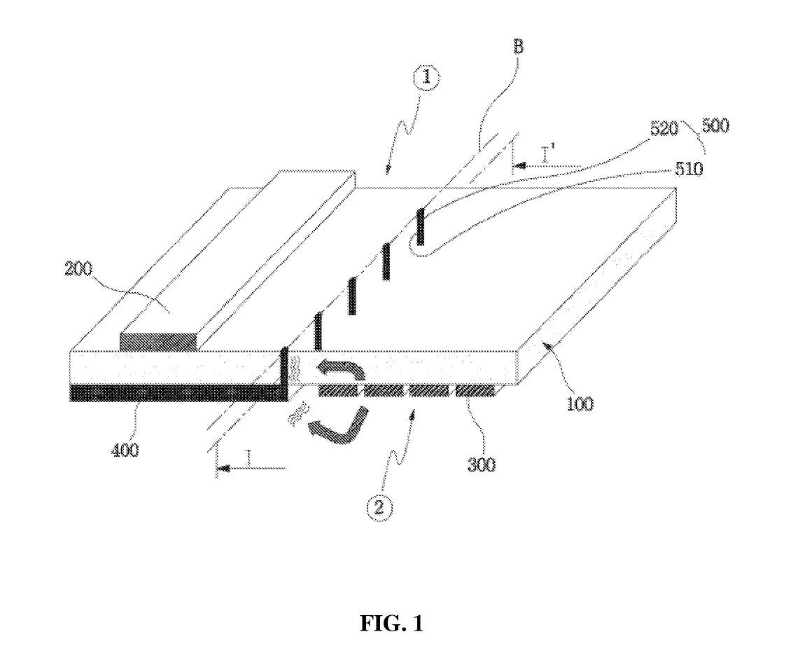

First, referring to FIG. 1, a board including a metallic shielding portion 500 including viaholes 510 and a metallic material 520 are described.

The flexible board for transmitting signals according to the present embodiment includes: a dielectric 100 on which different signal lines 200 and 300 are respectively disposed on independent separation regions \textcircled{1} and \textcircled{2} on opposite surfaces of opposite sides thereof; the metallic shielding portion 500 that is spaced apart from each other at intervals at a boundary B between the separation regions \textcircled{1} and \textcircled{2} and shields interference between the different signal lines 200 and 300; and a ground conductive layer 400 that is formed on a portion of the dielectric 100 and is electrically connected to the metallic shielding portion 500.

The dielectric 100 has a predetermined with, thickness, and area. As illustrated in FIG. 1, the dielectric 100 includes two separation regions \textcircled{1} and \textcircled{2} separated by the boundary B.

The separation regions \textcircled{1} and \textcircled{2} may include a first separation region \textcircled{1} and a second separation region \textcircled{2}.

The high frequency signal transmission line 200 is formed on an upper surface of the dielectric 100 that corresponds to the first separation region \textcircled{1}, and the data signal line 300 is formed on a lower surface of the dielectric 100 that corresponds to the second separation region \textcircled{2}. In this regard, the data signal line 300 may include a plurality of lines formed in parallel each other.

In particular, according to the present disclosure, the high frequency signal transmission line 200 and the data signal line 300 are located on opposite surfaces of opposite sides of the dielectric 100 with reference to the boundary B.

Also, as illustrated in FIG. 1, the ground conductive layer 400 is formed on the lower surface of the dielectric 100 that faces the first separation region \textcircled{1}. In this regard, the ground conductive layer 400 includes the boundary B.

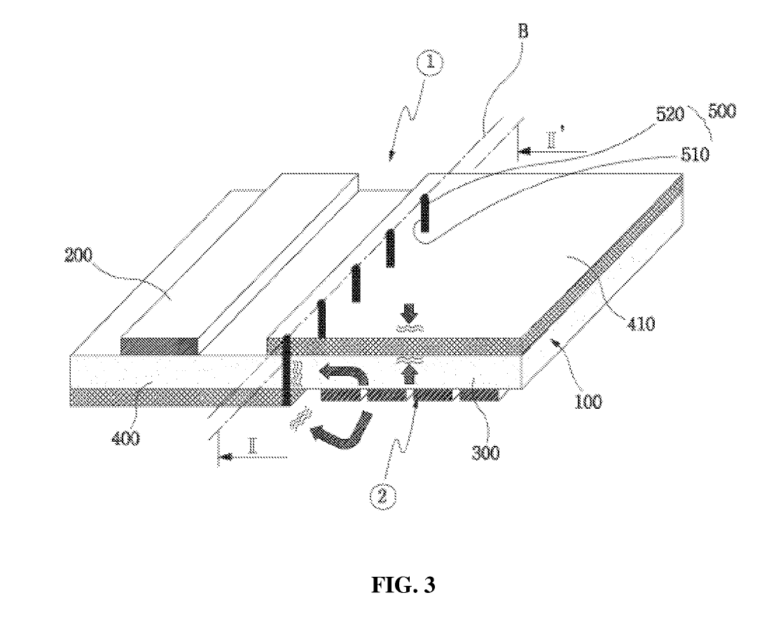

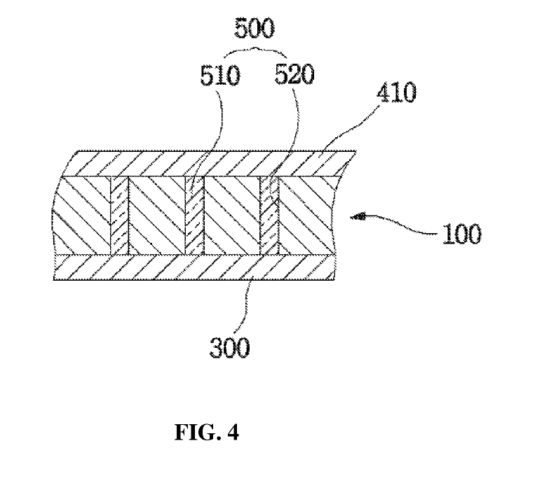

According to another embodiment, as illustrated in FIGS. 3 and 4, the ground conductive layer may include a first ground conductive layer 400 that includes the boundary B and is disposed on an outer surface of the dielectric 100 facing the first separation region \textcircled{1}, and a second ground conductive layer 410 that includes the boundary B and is disposed on an outer surface of the dielectric 100 facing the second separation region \textcircled{2}.

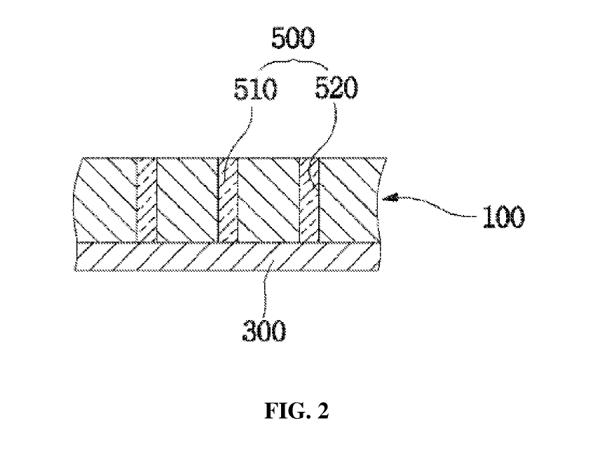

Referring to FIGS. 1 and 2, the metallic shielding portion 500 according to the present disclosure is formed spaced apart from each other at intervals along the boundary B that separates the separation regions \textcircled{1} and \textcircled{2}, and is electrically connected to the ground conductive layer 300.

More specifically, the metallic shielding portion 500 includes a plurality of viaholes 510 that are spaced apart from each other at intervals along the boundary B and pass through the dielectric 100, and the metallic material 520 filling the viaholes 510.

In this regard, the metallic material 520 can be copper and the viaholes 510 may be filled with the copper. Alternatively, a copper film may be formed on an inner circumference of the viaholes 510.

Accordingly, the high frequency signal transmission line 200 formed on the first separation region \textcircled{1} and the data signal line 300 formed on the second separation region \textcircled{2} which is disposed on a surface and a side opposite to those of the first separation region \textcircled{1} with respect to the boundary B may be easily shielded from each other by the metallic shielding portion 500 that is spaced apart from each other at intervals at the boundary B and is electrically connected to the ground conductive layer 300.

Also, as illustrated in FIGS. 3 and 4, the metallic shielding portion 500 may be electrically connected to the first ground conductive layer 400 and the second ground conductive layer 410.

Since a noise occurring in the data signal line 300 is not transmitted to the first separation region \textcircled{1}, a high frequency signal transmission using the high frequency signal transmission line 200 may be performed without interference of an external noise.

### Example 2

### Board Including Metallic Shielding Portion Having Planar Shape

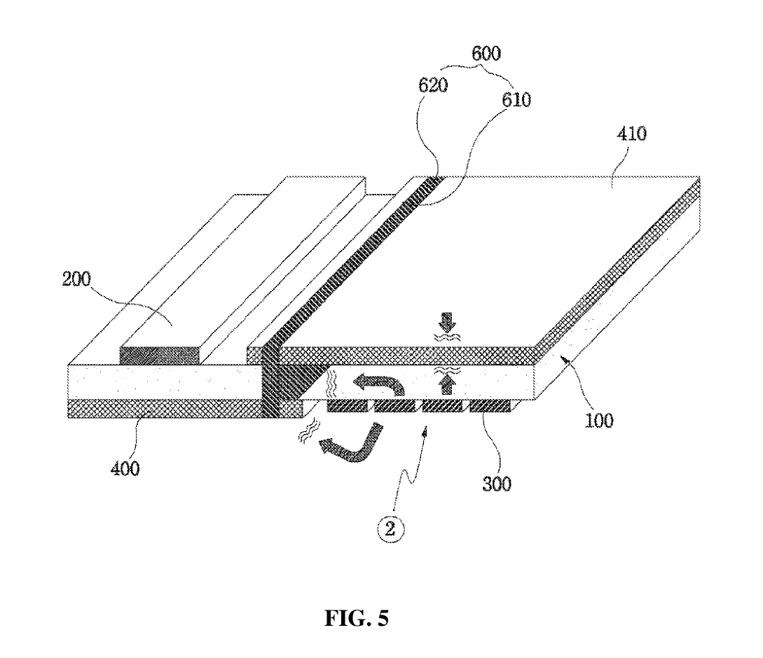

First, referring to FIG. 5, a board including a metallic shielding portion 600 having a planar shape is described.

The flexible board for transmitting signals according to the present embodiment includes: a dielectric 100 on which different signal lines 200 and 300 are respectively disposed on independent separation regions \textcircled{1} and \textcircled{2} on opposite surfaces of opposite sides thereof; a metallic shielding portion 500 that is disposed as one body at a boundary B between the separation regions \textcircled{1} and \textcircled{2} and shields interference between the different signal lines 200 and 300; and ground conductive layers 400 and 410 that are formed on portions of the dielectric 100 and are electrically connected to the metallic shielding portion 500.

The dielectric 100 has a predetermined with, thickness, and area. As illustrated in FIG. 5, the dielectric 100 includes two separation regions \textcircled{1} and \textcircled{2} separated by the boundary B.

The separation regions \textcircled{1} and \textcircled{2} may include a first separation region \textcircled{1} and a second separation region \textcircled{2}.

A high frequency signal transmission line 200 is formed on an upper surface of the dielectric 100 that corresponds to the first separation region \textcircled{1}, and a data signal line 300 is formed on a lower surface of the dielectric 100 that corresponds to the second separation region \textcircled{2}. In this regard, the data signal line 300 may include a plurality of lines formed in parallel each other.

In particular, according to the present disclosure, the high frequency signal transmission line 200 and the data signal line 300 are located on opposite surfaces of opposite sides of the dielectric 100 with reference to the boundary B.

Also, as illustrated in FIG. 5, the ground conductive layers 400 and 410 may include a first ground conductive layer 400 that includes the boundary B and is disposed on an outer surface of the dielectric 100 facing the first separation region \textcircled{1}, and a second ground conductive layer 410 that includes the boundary B and is disposed on an outer surface of the dielectric 100 facing the second separation region \textcircled{2}.

The metallic shielding portion 600 may have a shape embedded at the boundary B, and for example, may have a planar shape.

To form the metallic shielding portion 600, a separation hole 610 that has a planar shape having a predetermined width along the boundary B, and passes through the dielectric 100 is formed, and then the separation hole 610 is filled with a metallic material 620.

The metallic material 620 can be copper.

Accordingly, the high frequency signal transmission line 200 formed on the first separation region \textcircled{1} and the data signal line 300 formed on the second separation region \textcircled{2} on a surface and a side opposite to those of the first separation region \textcircled{1} with respect to the boundary B may be easily shielded from each other by the metallic shielding portion 600 that is disposed as one body at the boundary B, is electrically connected to the ground conductive layers 400 and 410, is formed of copper, and has a planar shape.

That is, since a noise occurring in the data signal line 300 is not transmitted to the first separation region \textcircled{1}, a high frequency signal transmission using the high frequency signal transmission line 200 may be performed without interference of an external noise.

### Example 3

### Board Including Shielding Film

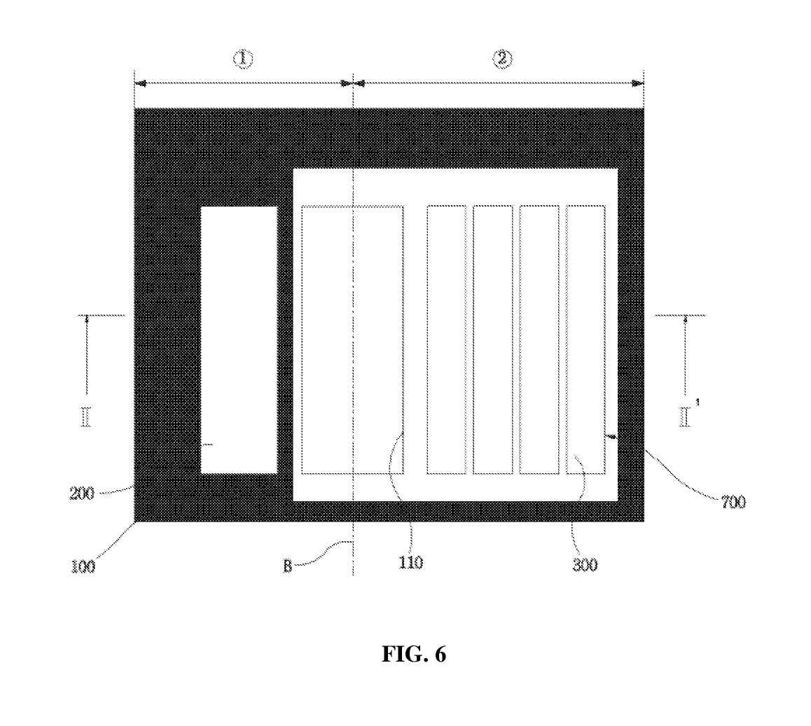

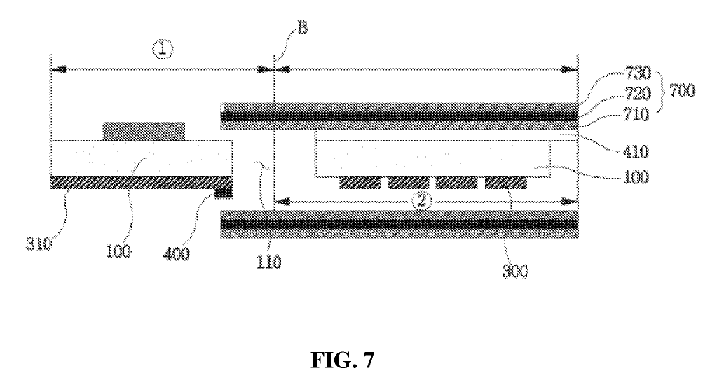

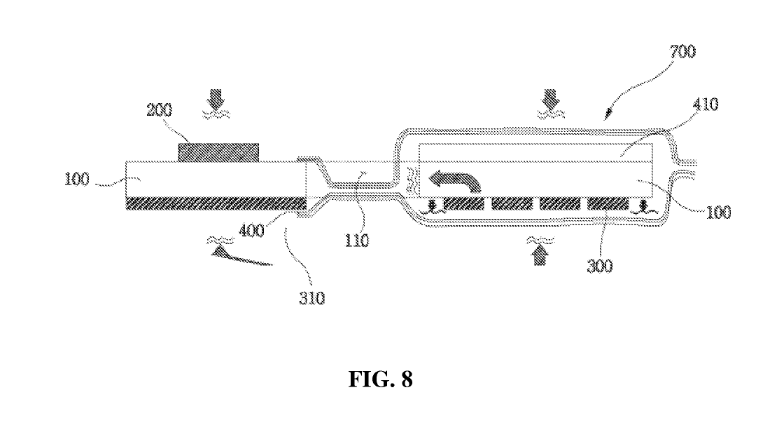

First, a board including a shielding film 700 is described with reference to FIGS. 6 to 8.

Referring to FIGS. 6 to 8, the flexible board for transmitting signals according to the present embodiment includes: a dielectric 100 on which different signal lines 200 and 300 are respectively disposed on independent separation regions \textcircled{1} and \textcircled{2} on opposite surfaces of opposite sides thereof; a spatial portion 110 that vertically passes through the dielectric 100 at a boundary B between the separation regions \textcircled{1} and \textcircled{2}; a pair of ground conductive layers 400 and 410 respectively formed on surfaces of the dielectric 100 facing the separation regions \textcircled{1} and \textcircled{2}; and the shielding film 700 that is disposed contacting each of upper and lower surfaces of the dielectric 100 above and under the dielectric 100 to surround the spatial portion 110 and any one of the separation regions \textcircled{1} and \textcircled{2}, and that shields interference of the different signal lines 200 and 300.

The different signal lines 200 and 300 include a high frequency signal transmission line 200 for transmitting a high frequency signal, and a data signal line 300 for transmitting a data signal; the separation regions \textcircled{1} and \textcircled{2} include a first separation region \textcircled{1} on which the high frequency signal transmission line 200 is formed, and a second separation region \textcircled{2} on which the data signal line 300 is formed; the boundary B is formed between the first separation region \textcircled{1} and the second separation region \textcircled{2}; and the shielding film 700 may surround the second separation region \textcircled{2}.

Also, a data signal line 310 may be further formed on the surface of the dielectric 100 facing the first separation region \textcircled{1}.

Also, the shielding film 700 includes a pair of shielding films which are each disposed above and under the dielectric 100, and each shielding film may include an adhesive layer 710 that is attached to a surface of the dielectric 100 and a protection film layer 730 that is formed on an outer surface of the adhesive layer 710.

In particular, in the present embodiment, a silver powder layer 720 formed of silver powder may be further formed between the adhesive layer 710 and the protection film layers 730.

A method of forming the spatial portion 110 and the shielding film 700 of the board including the shielding film 700 is described below.

The high frequency signal transmission line 200 is formed on an upper surface of the dielectric 100, and the data signal line 300 is formed on a lower surface of the dielectric 100 on the opposite side of the high frequency signal transmission line 200. Accordingly, the boundary B is formed between the first separation region \textcircled{1} on which the high frequency signal transmission line 200 is formed and the second separation region \textcircled{2} on which the data signal line 300 is formed.

Then, the dielectric 100 is bored to form a hole having a predetermined length and width at the boundary B. The bored hole is used as the spatial portion 110. Accordingly, the first separation region \textcircled{1} and the second separation region \textcircled{2} may be separated by the spatial portion 110.

Also, ground conductive layers 400 is formed on the lower surface of the dielectric 100 of the first separation region \textcircled{1} and ground conductive layers 410 is formed on the upper surface of the dielectric 100 of the second separation region \textcircled{2}.

Also, the shielding film 700 is prepared. The shielding film 700 is a flexible film and includes the adhesive layer 710 and the protection film layers 730 formed on the outer surface of the adhesive layer 710.

The shielding film 700 may include a pair of shielding films, which are respectively disposed above and under the dielectric 100.

Then, side portions of the shield films 700 are respectively attached to the second separation region \textcircled{2} and the upper surface of the dielectric 100 facing the second separation region \textcircled{2}, and other side portions of the shield films 700 are attached to the first separation region \textcircled{1} and the lower surface of the dielectric 100 facing the first separation region \textcircled{1}, covering upper and lower portions of the spatial portion 110. By doing so, the spatial portion 110 is structured enclosed by the shielding film 700.

Also, the shielding film 700 may further include a silver powder layer 720 formed by applying silver powder between the adhesive layer 710 and the protection film layers 730 so as to shield noise interference between the first and second separation regions \textcircled{1} and \textcircled{2}.

In turn, the data signal line 300 disposed on the second separation region \textcircled{2} is surrounded by the shielding film 700, thereby easily separated from the high frequency signal transmission line 200 on the first separation region \textcircled{1}.

Also, according to an embodiment of the present disclosure, instead of the shielding film 700, silver powder may be deposited on a region on which the shielding film 700 is attached.

Accordingly, on the dielectric 100, the high frequency signal transmission line 200 disposed on the first separation region \textcircled{1}, and the data signal line 300 disposed on the second separation region \textcircled{2} on a surface and a side opposite to those of the first separation region \textcircled{1} with respect to the boundary B may be easily separated from each other by the spatial portion 110 at the boundary B enclosed by the shield film 700 or silver powder deposited adjacent to the spatial portion 110.

Since a noise occurring in the data signal line 300 is not transmitted to the first separation region \textcircled{1}, a high frequency signal transmission using the high frequency signal transmission line 200 may be performed without interference of an external noise.

According to the present disclosure, a high frequency signal transmission line and a data signal line are disposed on opposite surfaces of opposite sides of an identical board, and interference between different signal lines is shielded to reduce a noise of a high frequency signal.

While the present disclosure has been particularly shown and described with reference to exemplary embodiments, it will be understood by one of ordinary skill in the art that various changes in form and details may be made therein without departing from the scope of the present disclosure.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A flexible board for transmitting signals, the flexible board comprising:
a dielectric on which signal lines are respectively disposed on independent separation regions on opposite surfaces of opposite sides thereof;
a metallic shielding portion that is spaced apart from each other at intervals at a boundary between the separation regions and shields interference between the different signal lines; and
a ground conductive layer that is formed on a portion of the dielectric and is electrically connected to the metallic shielding portion.

2. The flexible board of claim 1, wherein the signal lines comprise a high frequency signal transmission line for transmitting a high frequency signal, and a data signal line for transmitting a data signal,
the separation regions comprise a first separation region on which the high frequency signal transmission line is formed, and a second separation region on which the data signal line is formed, and
the boundary is formed between the first separation region and the second separation region.

3. The flexible board of claim 2, wherein the ground conductive layer is formed comprising the boundary on an outer surface of the dielectric facing the first separation region.

4. The flexible board of claim 1, wherein the ground conductive layer comprises:
a first ground conductive layer formed comprising the boundary on an outer surface of the dielectric facing the first separation region; and
a second ground conductive layer formed comprising the boundary on an outer surface of the dielectric facing the second separation region.

5. The flexible board of claim 1, wherein the metallic shielding portion comprises:
a plurality of viaholes that are spaced apart from each other at intervals and pass through the dielectric; and
a metallic material that fills the viaholes.

6. A flexible board for transmitting signals, the flexible board comprising:
a dielectric on which signal lines are respectively disposed on independent separation regions on opposite surfaces of opposite sides thereof;
a metallic shielding portion that is disposed as one body at a boundary between the separation regions and shields interference between the signal lines; and
a ground conductive layer that is formed on a portion of the dielectric and is electrically connected to the metallic shielding portion.

7. The flexible board of claim 6, wherein the signal lines comprise a high frequency signal transmission line for transmitting a high frequency signal, and a data signal line for transmitting a data signal,
the separation regions comprise a first separation region on which the high frequency signal transmission line is formed, and a second separation region on which the data signal line is formed, and
the boundary is formed between the first separation region and the second separation region.

8. The flexible board of claim 7, wherein the ground conductive layer is formed comprising the boundary on an outer surface of the dielectric facing the first separation region.

9. The flexible board of claim 7, wherein the ground conductive layer comprises:
a first ground conductive layer formed comprising the boundary on an outer surface of the dielectric facing the first separation region; and
a second ground conductive layer formed comprising the boundary on an outer surface of the dielectric facing the second separation region.

10. The flexible board of claim 6, wherein the metallic shielding portion is formed in a planar shape, and comprises a separation hole that is formed in a planar shape having a predetermined width along the boundary and passes through the dielectric, and a metallic material that fills the separation hole.

11. A flexible board for transmitting signals, the flexible board comprising:
a dielectric on which signal lines are respectively disposed on independent separation regions on opposite surfaces of opposite sides thereof;
a spatial portion that vertically passes through the dielectric at a boundary between the separation regions;
a pair of ground conductive layers respectively formed on surfaces of the dielectric facing the separation regions; and
a shielding film that is disposed contacting each of upper and lower surfaces of the dielectric above and under the dielectric to surround the spatial portion and any one of the separation regions, and that shields interference of the signal lines.

12. The flexible board of claim 11, wherein the signal lines comprise a high frequency signal transmission line for transmitting a high frequency signal, and a data signal line for transmitting a data signal,
the separation regions comprise a first separation region on which the high frequency signal transmission line is formed, and a second separation region on which the data signal line is formed,
the boundary is formed between the first separation region and the second separation region, and
the shielding film surrounds the second separation region.

13. The flexible board of claim 12, further comprising a data signal line disposed on the surface of the dielectric facing the first separation region.

14. The flexible board of claim 11, wherein the shielding film comprises a pair of shield films, which are respectively disposed above and under the dielectric,
wherein each shielding film comprises an adhesive layer attached on a surface of the dielectric, and a protection film layer formed on an outer surface of the adhesive layer.

15. The flexible board of claim 14, wherein a silver (Ag) powder layer comprising silver powder is further formed between the adhesive layer and the protection film layer.
